(19) United States
(12) Patent Application Publication
(10) Pub. No.: US 2022/0077223 A1
(43) Pub. Date: Mar. 10, 2022

(54) PROCESSES, ARTICLES AND APPARATUS THAT INCORPORATE SEMICONDUCTOR SWITCHES AND DRIVE CIRCUITRY ON COMPOUND SEMICONDUCTOR CHIPLETS

(71) Applicant: LUMIODE, INC., Bronx, NY (US)

(72) Inventors: Vincent Lee, New York, NY (US); Brian Tull, Englewood Cliffs, NJ (US); Ioannis Kymissis, New York, NY (US); Yu-Jen Hsu, Forest Hills, NY (US)

(21) Appl. No.: 17/417,889

(22) PCT Filed: Dec. 18, 2019
(86) PCT No.: PCT/US2019/067207

§ 371 Date: Jun. 24, 2021

Related U.S. Application Data
(60) Provisional application No. 62/789,397, filed on Jan. 7, 2019.

(51) Int. Cl. H01L 27/15; H01L 33/00; H01L 25/00; H01L 25/065

(52) U.S. Cl. CPC H01L 27/15; H01L 33/0093; H01L 25/0655; H01L 25/50; H01L 33/0095

(57) ABSTRACT

This invention relates to the fabrication of semiconductor devices using released elements of a semiconductor material (chiplets) which are co-integrated with thin film transistors to implement addressing, switching, amplification, memory, low voltage logic, or other electronic functionality. These chiplets are released from their initial substrate and distributed across a larger area to form a complete system as part of the manufacturing process of a final system.

### TECHNICAL FIELD

This description generally relates to the fabrication of semiconductor devices and systems, and in particular relates to fabrication of semiconductor devices employing chiplets.

### BACKGROUND

### Description of the Related Art

The fabrication of compound semiconductor devices using small fragments of direct bandgap semiconductor materials has emerged as a technique for creating a variety of display, communication, and logic products. Semiconductors that have favorable optoelectronic properties due to their direct bandgap are particularly suitable for the fabrication of certain electronic components, e.g., lasers, LEDs, photodetectors, but typically are not suitable for fabrication of other electronic components, e.g., transistors. In order to provide switching, amplification, and device selection it may be necessary to hybridize electronic components employing a particular semiconductor material with electronic components employing a different semiconductor material, for example to provide transistors that offer switching and drive circuitry. There are also applications in the compound semiconductor field (e.g., high voltage drive) that produce transistors with switching characteristics that are limited in their applicability.

One approach that has been previously used to create hybrid devices with a mix of favorable properties is to bond or solder compound semiconductor optical components to single crystal silicon substrates, and to use silicon transistors on the single crystal silicon substrate for selection and drive functionality. This approach has been used both for arrays of optical components on compound semiconductor substrates as well as on individual chiplets which are distributed on a substrate. For example, Herrensdorf, et al. (Active-Matrix GaN Micro Light-Emitting Diode Display With Unprecedented Brightness (IEEE Transactions on Electron Devices Vol. 62, No. 6, page 1918 (June 2015)) applied this approach to a relatively sophisticated array of devices fabricated on a compound semiconductor wafer which has optoelectronic functionality but no available transistors, and a silicon integrated circuit which provides the drive and control circuitry for the device.

Radauscher, et al. (Passive Matrix Displays with Transfer-Printed Microscale Inorganic LEDs, Invited Paper, 55-1, M. Meiti; SID 2016 Digest, p 743) employs another approach to silicon/compound semiconductor hybridization, in which a compound semiconductor is partitioned into chiplets and released, as are silicon integrated circuits. These devices are then placed on a substrate and connected using interconnect fabricated using traditional thin film semiconductor processing approaches.

A second approach to realizing this functionality is to bond the chiplets to a glass or other substrate with a thin film transistor backplane. This transistor backplane can then provide the switching and selection required to implement the active matrix functionality required for the display component. In U.S. Pat. No. 9,159,700 (Sakariya et al.), for example, an array is envisioned in which compound semiconductor micro-LED chiplets are bonded to a glass substrate and are connected to a pre-fabricated TFT-containing backplane, e.g., through vias, to provide the required switching and addressing functionality to produce a display.

### BRIEF SUMMARY

In at least one aspect, fabrication of semiconductor devices can be summarized as fabricating a first type of electronic device employing a first semiconductor layer, fabricating a second type of electronic device employing a second semiconductor layer, forming chiplets, and transferring the chiplets to a final substrate either directly or via an intermediate substrate. While the material of the first and the second semiconductor layers may be the same semiconductor, in many implementations these will advantageously be two different types of semiconductor materials.

In at least one aspect, the fabrication of semiconductor devices described herein can be summarized as using small elements of a semiconductor material (chiplets) fabricated using a first semiconductor material having a first set of physical and/or operational characteristics that are suitable or even optimized for a first function (e.g., a non-transistor functionality such as emission or detection of light), and combining such with a second semiconductor material having a second set of physical and/or operational characteristics that are suitable or even optimal for a second function (e.g., thin film transistors for addressing, switching, amplification, memory, low voltage logic, or other electronic functionality).

In yet another aspect, a fabrication process can be summarized as a semiconductor wafer with a specialized functionality is processed to implement functional devices. A thin film semiconductor is deposited and processed on this wafer to implement a second functionality. Chiplets with both semiconductor functionalities are then released and transferred to a target substrate, implementing the two functionalities in a single structure.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIGS. 1A-1G are cross-sectional views illustrating a sequence of operations to fabricate an electronic device according to at least one illustrated implementation, which employs a temporary carrier substrate to invert chiplets with LEDs allowing formation of transistor circuitry from a back surface side before transfer to a final substrate via pick and place machinery or an elastomeric stamp in the inverted orientation.

FIGS. 2A-2G are cross-sectional views illustrating a sequence of operations to fabricate an electronic device according to at least one illustrated implementation, which employs a temporary carrier substrate to invert chiplets with LEDs allowing formation of transistor circuitry from a back surface side thereof before transfer to a final substrate via selective laser release in the inverted orientation.

FIGS. 3A-30 are cross-sectional views illustrating a sequence of operations to fabricate an electronic device according to at least one illustrated implementation, in which transistor circuitry is formed from a front surface side over LEDs before direct transfer, without a temporary carrier or intermediate substrate, to a final substrate in an inverted orientation.

FIGS. 4A-4H are cross-sectional views illustrating a sequence of operations to fabricate an electronic device according to at least one illustrated implementation, in which transistor circuitry is formed from a front surface side over LEDs along with solder bumps before direct transfer, without a temporary carrier or intermediate substrate, to a final substrate in an inverted orientation, followed by a solder reflow operation and addition of color conversion material.

FIGS. 5A-5G are cross-sectional views illustrating a sequence of operations to fabricate an electronic device according to at least one illustrated implementation, in which transistor circuitry is formed from a front surface side over LEDs before direct transfer, without a temporary carrier or intermediate substrate, to a final substrate in an un-inverted orientation via release of tethered chiplets.

FIGS. 6A-6I are cross-sectional views illustrating a sequence of operations to fabricate an electronic device according to at least one illustrated implementation, in which transistor circuitry is formed from a front surface side over LEDs before direct transfer, without a temporary carrier or intermediate substrate, to a final substrate in an inverted orientation via release of tethered chiplets.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, certain structures associated with light emitting diodes (LEDs), drive circuits, integrated circuits and fabrication equipment have not been shown or described in detail to avoid unnecessarily obscuring descriptions of the various implementations and embodiments.

Unless the context requires otherwise, throughout the specification and claims which follow, the word “comprise” and variations thereof, such as, “comprises” and “comprising” are to be construed in an open, inclusive sense, that is as “including, but not limited to.”

Reference throughout this specification to “one implementation” or “an implementation” or “one embodiment” or “an embodiment” means that a particular feature, structure or characteristic described in connection with the embodiment is included in at least one implementation or at least one embodiment. Thus, the appearances of the phrases “one implementation” or “an implementation” or “in one embodiment” or “in an embodiment” in various places throughout this specification are not necessarily all referring to the same implementation or the same embodiment. Furthermore, the particular features, structures, or characteristics may be combined in any suitable manner in one or more implementations or in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

The headings and Abstract of the Disclosure provided herein are for convenience only and do not interpret the scope or meaning of the implementations or embodiments.

Described herein are fabrication processes or methods, and structures or configurations in which chiplets are formed and isolated using a first semiconductor material. These first semiconductor material may have certain physical or operation characteristics that allow electronic components on the chiplets to have a certain functionality that is enhanced or optimized over what can be realized using other semiconductors. Thus, the chiplets may carry electronic components with functions that are particularly suitable or take advantage of the properties of the first semiconductor, e.g. high speed switching operations for transistors (such as a high electron mobility transistor (HEMT)), lasing, LED functionality, or photodetector functionality. A thin film semiconductor is deposited on the first semiconductor and processed to fabricate field effect transistors and circuits for control of the semiconductor (e.g. via lithography, doping, recrystallization, or other techniques). These chiplets with co-integrated control circuitry are then released and transferred to another substrate. The chiplets with integral control are then addressed and driven using the thin film semiconductors deposited and patterned on the compound semiconductor. It is possible to use an intermediate transfer substrate (such as an interposer), in which case the processing and singulation can occur i) while on the first substrate, ii) while on the intermediate transfer substrate, or iii) after transfer to a target or final substrate. While many of the specific examples discussed herein are described in term of light emitting diodes (LEDs), those are not intended to be limiting. For example, various electronic components, for example lasers, photodetectors and high speed transistors could be fabricated in lieu of, or in addition to, the exemplary LEDs.

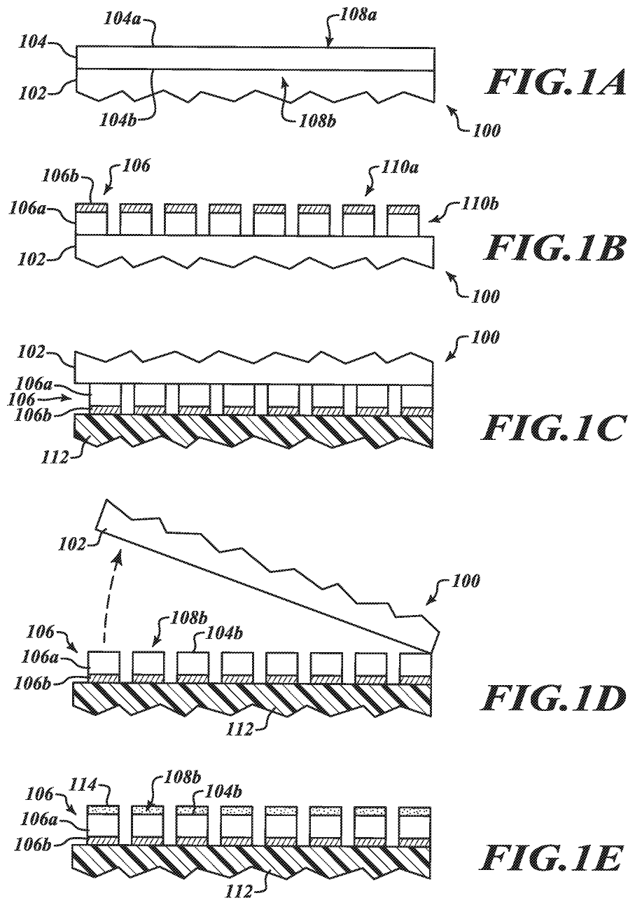

FIGS. 1A-1G show a sequence of operations to fabricate an electronic device according to at least one illustrated implementation, which employs a temporary carrier or intermediate substrate to invert chiplets with LEDs allowing formation of transistor circuitry from a back surface side before transfer to a final substrate via pick and place machinery or an elastomeric stamp in the inverted orientation. In the implementation of FIGS. 1A-1G, an LED epiwafer is processed to create individual chiplets. The chiplets are transferred en masse to a temporary carrier or intermediate substrate, and released from a growth substrate of the LED epiwafer. TFT circuitry is deposited and structured on the chiplets The chiplets are then individually transferred to a target or final substrate and connected using a pick and place or elastomeric stamp transfer process. This can optionally be followed by a deposition of one or more color conversion layers and/or fabrication of one or more light extraction features to improve the extraction of light from the LEDs.

In particular, FIG. 1A shows a light emitting diode (LED) wafer (e.g., epiwafer) 100 comprising a growth substrate 102 and a first semiconductor material in the form of an epitaxial LED layer 104, carried by the growth substrate 102. The epitaxial LED layer 104 has a front surface 104a, a back surface 104b opposed from the front surface 104a across a thickness of the epitaxial LED layer 104. The back surface 104b is at least proximally more adjacent the growth substrate 102 relative to the front surface 104a.

FIG. 1B shows fabrication of a plurality of a first type of semiconductor based electronic device in the first semiconductor material, illustrated as light emitting diodes 106 (only one called out). The LEDs 106 comprise a light generation or recombination region 106a of the epitaxial LED layer 104, and contacts 106b. The contacts 106b may be fabricated by depositing electrically conductive material, and patterning the electrically conductive material. Notably, the LEDs 106 are fabricated from a front surface side 108a. As also illustrated in FIG. 1B the LEDs 106 are structured into chiplets 110a, 110b (only two called out, collectively 110).

FIG. 10 shows the resulting structure (e.g., chiplets 110 coupled to growth substrate 102) inverted, with the LEDs 106 bonded to a temporary carrier or intermediary substrate 112. The contacts 106b may be proximally adjacent the temporary carrier or intermediary substrate 112.

FIG. 1D shows removal of the growth substrate 102 to expose the back surface 104b of the LEDs 106 for further processing from a back surface side 108b. The growth substrate 102 can be removed via a variety of methods, for example via one or more of laser lift-off operations, etching operations and/or back-grinding operations (e.g., chemical-mechanical planarization).

FIG. 1E shows fabrication of thin film transistors (TFTs) 114 (only one called out) from a back surface side 108b. Thus, the TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114.

FIG. 1F shows the chiplets 110 being transferred to a target or final substrate 116 and mounted or attached thereto. As illustrated in FIG. 1F, pick and place machinery, for example a transfer head 118, or an elastomeric stamp may be employed to retrieve the chiplets 110 from the temporary carrier or intermediate substrate 112 and transfer the chiplets 110 to the target or final substrate 116.

FIG. 1G shows depositing and patterning fabrication operations on the target or final substrate 116 to provide interconnects 120 to the drive circuitry. Such may include various silicon fabrication operations including depositing of electrically conductive materials, depositing of dielectric material, and patterning (e.g., masking, etching). While not illustrated in FIGS. 1A-1G, fabrication can further include addition of color conversion material and/or formation of light extraction features.

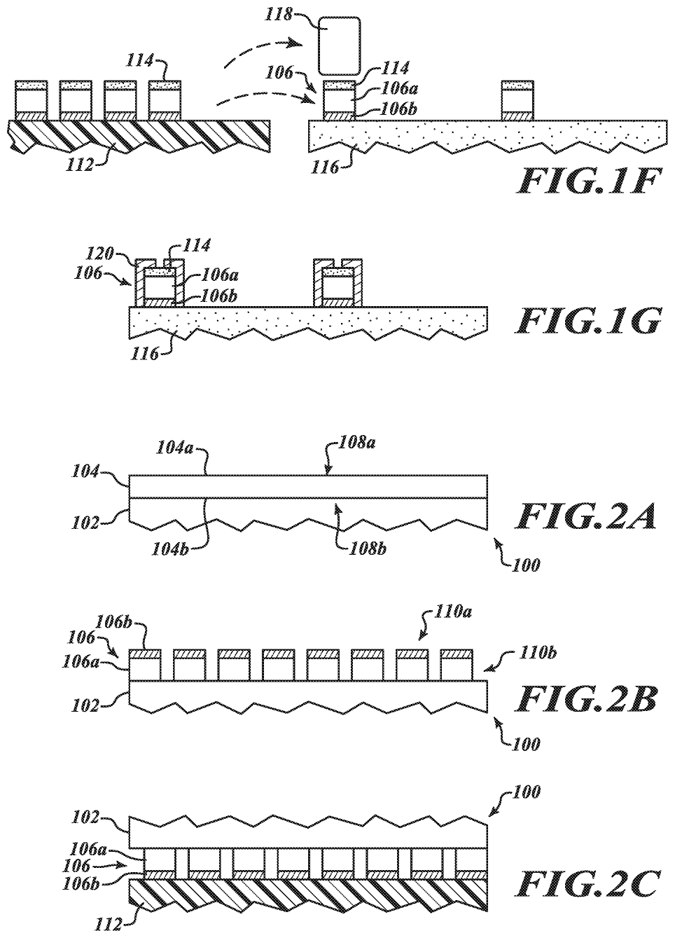

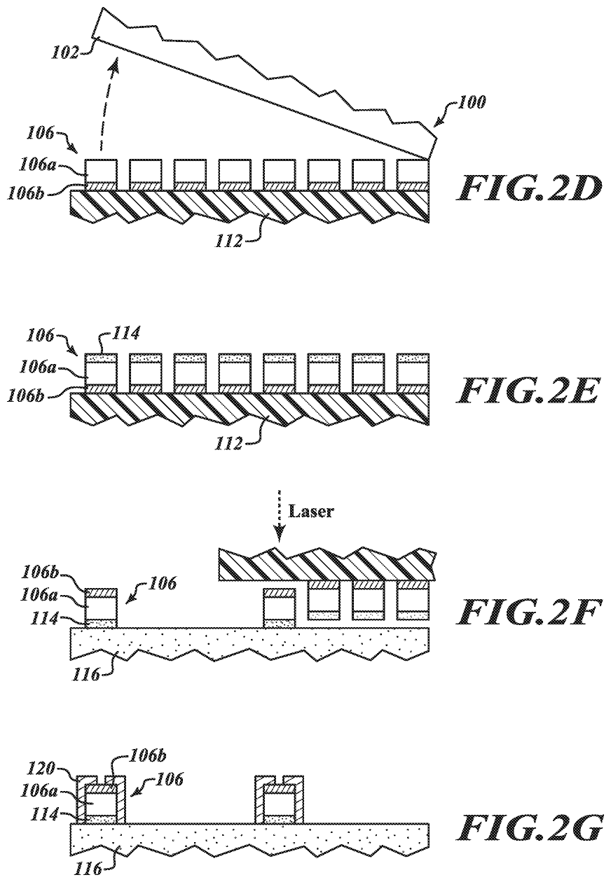

FIGS. 2A-2G show a sequence of operations to fabricate an electronic device according to at least one illustrated implementation, which employs a temporary carrier substrate to invert chiplets with LEDs allowing formation of transistor circuitry from a back surface side thereof before transfer to a final substrate via selective laser release in the inverted orientation. In the implementation of FIG. 2A-2G, an LED epiwafer is processed to create individual chiplets. The LED wafer is structured into chiplets, and processed to incorporate thin film transistors. The chiplets are transferred to a temporary carrier or intermediate substrate, and released from a growth substrate of the epiwafer. TFT circuitry is deposited and structured on the chiplets. The chiplets are then transferred to a target or final substrate and electrically connected to circuitry. This can optionally be followed by the deposition of one or more color conversion layers and/or light extraction features to improve the extraction of light from the LEDs.

Many of the structures and operations are similar, or even identical, to those illustrated and described with reference to FIGS. 1A-1G. These similar or identical structures and operations are identified below using the same reference numbers as used in FIGS. 1A-1G.

In particular, FIG. 2A shows a light emitting diode (LED) wafer 100 comprising a growth substrate 102 and a first semiconductor material in the form of an epitaxial LED layer 104, carried by the growth substrate 102. The epitaxial LED layer 104 has a front surface 104a, a back surface 104b opposed from the front surface 104a across a thickness t of the epitaxial LED layer 104. The back surface 104b is at least proximally more adjacent the growth substrate 102 relative to the front surface 104a.

FIG. 2B shows fabrication of a plurality of a first type of semiconductor based electronic device in the first semiconductor material, illustrated as light emitting diodes 106 (only one called out). The LEDs 106 comprise a light generation or recombination region 106a of the epitaxial LED layer 104, and contacts 106b. The contacts 106b may be fabricated by depositing electrically conductive material, and patterning the electrically conductive material. Notably, the LEDs 106 are fabricated from a front surface side 108a. As also illustrated in FIG. 2B the LEDs 106 are structured into chiplets 110a, 110b (only two called out, collectively 110).

FIG. 20 shows the resulting structure (e.g., chiplets 110 coupled to growth substrate 102) inverted, with the LEDs 106 bonded to a temporary carrier or intermediary substrate 112. The contacts 106b may be proximally adjacent the temporary carrier or intermediary substrate 112.

FIG. 2D shows removal of the growth substrate 102 to expose the back surface 104b of the LEDs 106 for further processing from a back surface side 108b. The growth substrate 102 can be removed via a variety of methods, for example via one or more of laser lift-off operations, etching operations and/or back-grinding operations (e.g., chemical-mechanical planarization).

FIG. 2E shows fabrication of thin film transistors (TFTs) 114 (only one called out) from a back surface side 108b. The TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114.

FIG. 2F shows the chiplets 110 being transferred to a target or final substrate 116 and mounted or attached thereto. As illustrated in FIG. 1F, a laser release operation may be employed to release the chiplets 110 from the temporary carrier or intermediate substrate 112 and transfer the chiplets 110 to the target or final substrate 116.

FIG. 2G shows depositing and patterning fabrication operations on the target or final substrate 116 to provide interconnects 120 to the drive circuitry. Such may include various silicon fabrication operations including depositing of electrically conductive materials, depositing of dielectric material, and patterning (e.g., masking, etching, polishing). While not illustrated in FIGS. 1A-1G, fabrication can further include addition of color conversion material and/or formation of light extraction features.

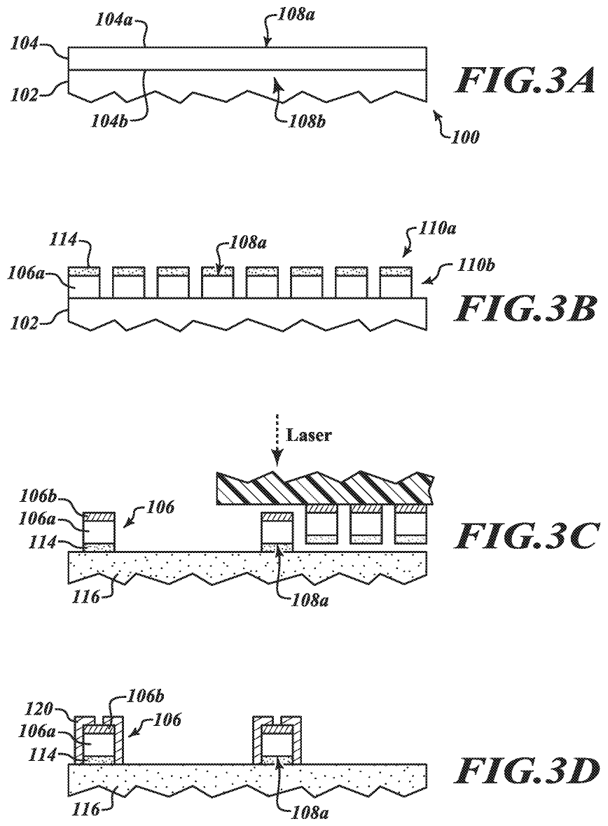

FIGS. 3A-3D show a sequence of operations to fabricate an electronic device according to at least one illustrated implementation, in which transistor circuitry is formed from a front surface side over LEDs before direct transfer, without a temporary carrier or intermediate substrate, to a final substrate in an inverted orientation. In the implementation of FIGS. 3A-3D, an LED epiwafer is processed to create individual chiplets. TFT circuitry is deposited and structured on the chiplets. The chiplets are then individually transferred to a target or final substrate and electrically connected. The transfer is conducted without the use of a temporary carrier or intermediate substrate. This can optionally be followed by a deposition of one or more color conversion layers and/or fabrication of one or more light extraction features to improve the extraction of light from the LEDs.

Many of the structures and operations are similar, or even identical, to those illustrated and described with reference to FIGS. 1A-1G. These similar or identical structures and operations are identified below using the same reference numbers as used in FIGS. 2A-2G.

In particular, FIG. 3A shows a light emitting diode (LED) wafer 100 comprising a growth substrate 102 and a first semiconductor material in the form of an epitaxial LED layer 104, carried by the growth substrate 102. The epitaxial LED layer 104 has a front surface 104a, a back surface 140b opposed from the front surface 104a across a thickness t of the epitaxial LED layer 104. The back surface 104b is at least proximally more adjacent the growth substrate 102 relative to the front surface 104a.

FIG. 3B shows fabrication of a plurality of a first type of semiconductor based electronic device in the first semiconductor material, illustrated as light emitting diodes 106 (only one called out). The LEDs 106 comprise a light generation or recombination region 106a of the epitaxial LED layer 104, and contacts 106b. The contacts 106b may be fabricated by depositing electrically conductive material, and patterning the electrically conductive material. Notably, the LEDs 106 are fabricated from a front surface side 108a.

FIG. 3B also shows fabrication of thin film transistors (TFTs) 114 (only one called out) from the front surface side 108a (in contrast to the implementations of FIGS. 1A-1G and 2A-2G where the TFTs are fabricated from the back surface side 108b). The TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114.

As also illustrated in FIG. 3B the LEDs 106 with the TFTs 114 are structured into chiplets 110a, 110b (only two called out, collectively 110).

FIG. 3C shows the resulting structure (e.g., chiplets 110 coupled to growth substrate 102) inverted, with the LEDs 106 and TFTs 114 bonded to a target or final substrate 116 in the inverted orientation (e.g., the TFTs 114 more proximally adjacent the target or final substrate 112 than the LEDs 106). The chiplets 110 may, for example, be transferred to the target or final substrate 116 and mounted or attached thereto via a structured laser processing release operation which releases the chiplets 110 from the growth substrate 102 and to transfer the chiplets 110 to the target or final substrate 116.

FIG. 3D shows depositing and patterning fabrication operations on the target or final substrate 116 to provide interconnects 120 to the drive circuitry. Such may include various silicon fabrication operations including depositing of electrically conductive materials, depositing of dielectric material, and patterning (e.g., masking, etching, polishing). While not illustrated in FIGS. 3A-3d, fabrication can further include addition of color conversion material and/or formation of light extraction features.

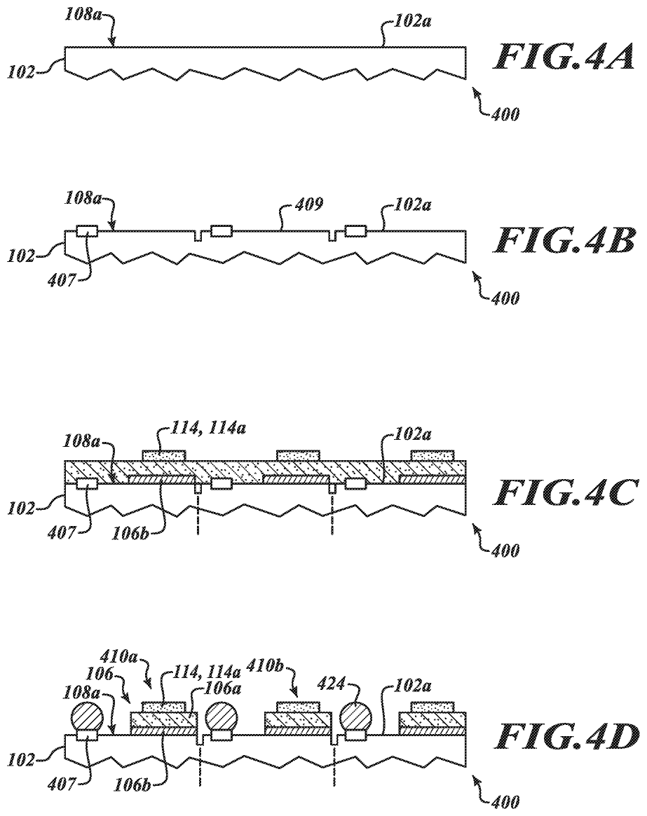

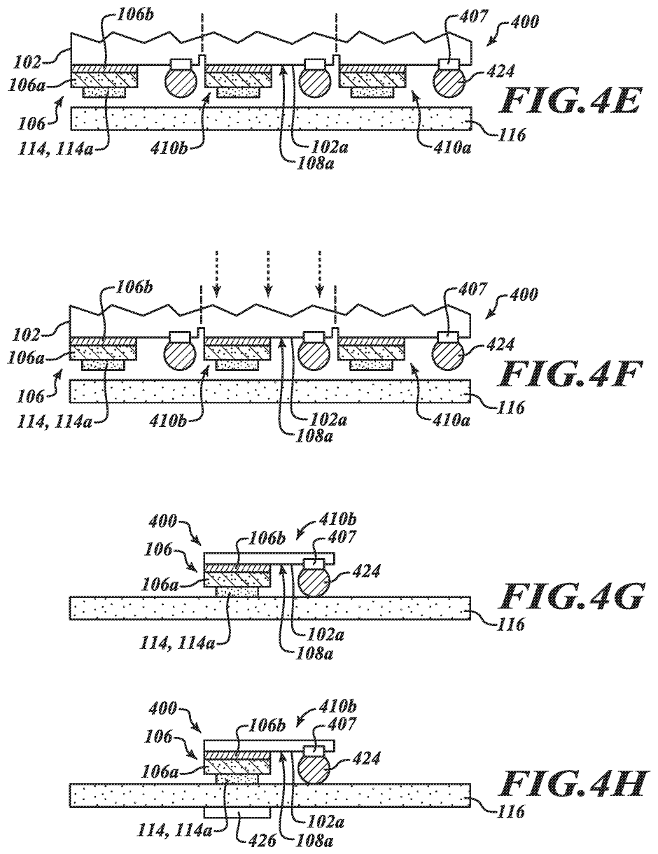

FIGS. 4A-4H show a sequence of operations to fabricate an electronic device according to at least one illustrated implementation, in which transistor circuitry is formed from a front surface side over LEDs along with solder bumps before direct transfer, without a temporary carrier or intermediate substrate, to a final substrate in an inverted orientation, followed by a solder reflow operation and addition of color conversion material. Many of the structures and operations are similar, or even identical, to those illustrated and described with reference to FIGS. 1A-1G. These similar or identical structures and operations are identified below using the same reference numbers as used in FIGS. 1A-1G.

In particular, FIG. 4A shows a light emitting diode (LED) wafer 400 comprising a growth substrate 102. The LED wafer 400 has a front surface 102a.

FIG. 4B shows fabrication of a plurality of a first type of semiconductor based electronic device in a first semiconductor material, illustrated as light emitting diodes 106 (only one called out), with electrodes 407 and mesas 409. Where a first set of electronic components will be LEDs, the first semiconductor material may, for example, take the form of an epitaxial LED layer carried by the growth substrate 102. The LEDs 106 comprise a light generation or recombination region 106a (FIG. 4C) of the epitaxial LED layer 104 (FIG. 4C), and contacts 106b (FIG. 4C). The electrodes 106b may be fabricated by depositing electrically conductive material, and patterning the electrically conductive material. Notably, the LEDs 106 are fabricated from a front surface side 108a.

FIG. 4C shows fabrication of thin film transistors (TFTs) 114 (only one called out) from the front surface side 108a. The TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114. As noted, the first semiconductor material is not limited to semiconductors suitable for formation of LEDs, and first set of electronic devices are not limited to LEDs. In other implementations, the first semiconductor material may be particularly suitable for fabrication of semiconductor based lasers, photo-detection, or high speed switching, and the first set of electronic devices may be semiconductor lasers, photodetectors, or high speed switches (e.g., high speed transistors), respectively.

FIG. 4D shows fabrication of interconnects 422 and addition of solder bumps 424 from the front surface side 108a. As also illustrated in FIG. 4D, the LEDs 106, TFTs 114, interconnects 422, and solder bumps 424 are structured into chiplets 410a, 410b (only two called out, collectively 410).

FIG. 4E shows the resulting structure (e.g., chiplets 410 on growth substrate 102) inverted and positioned proximate a target or final substrate 116. The resulting structure may have the interconnects positioned more proximally adjacent the target or final substrate 116 than the LEDs 106,

FIG. 4F shows the chiplets 410 being transferred to a target or final substrate 116 and mounted or attached thereto. As illustrated in FIG. 4F, a laser release operation may be employed to release the chiplets 410 from growth substrate 102, without the use of any temporary carrier or intermediate substrates, and transfer the chiplets 410 directly to the target or final substrate 116.

FIG. 4G shows a solder reflow operation, in which a temperature is raised to cause solder reflow. The solder bumps 424 may thus reflow to establish electrically communicative coupling between the chiplets 410 and electrically conductive pads or traces on the target or final substrate 116.

FIG. 4H shows the addition of one or more color conversion materials 426. For example, one or more layers of color conversion material 426 may be deposited, and optionally patterned on the target or final substrate 116. The depositing or patterning may cause portions of the color conversion material 426 to be in registration with respective ones of the LEDs 106. While not illustrated, the fabrication process can include the formation of one or more light extraction features, which may include registration of light extraction features with respective ones of the LEDs 106.

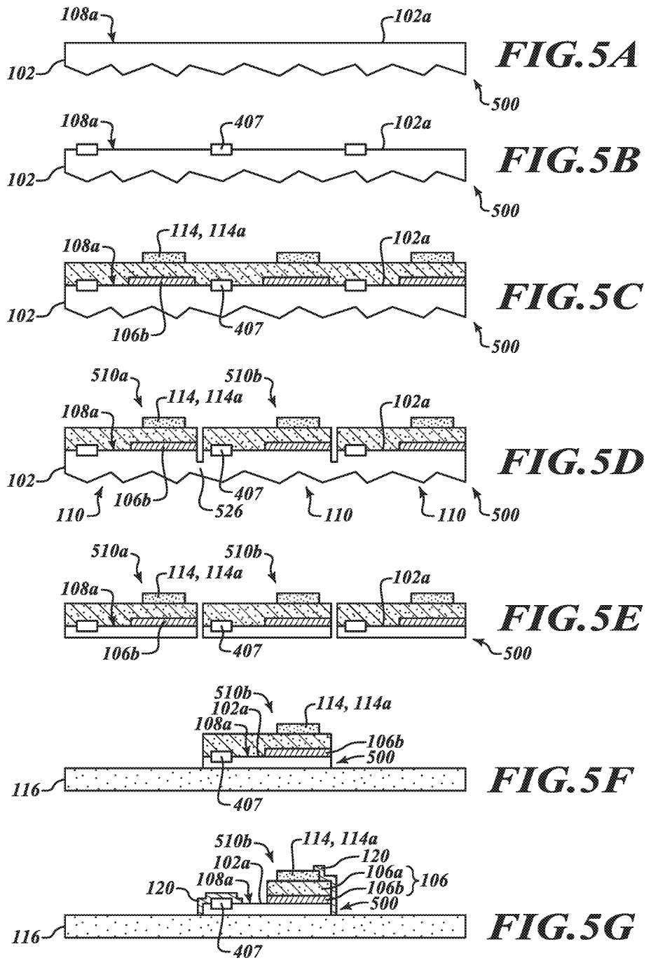

FIGS. 5A-5G show a sequence of operations to fabricate an electronic device according to at least one illustrated implementation, in which transistor circuitry is formed from a front surface side over LEDs before direct transfer, without a temporary carrier or intermediate substrate, to a final substrate in an un-inverted orientation via release of tethered chiplets. Many of the structures and operations are similar, or even identical, to those illustrated and described with reference to FIGS. 4A-4H. These similar or identical structures and operations are identified below using the same reference numbers as used in FIGS. 4A-4H.

In particular, FIG. 5A shows a light emitting diode (LED) wafer 400 comprising a growth substrate 102. The LED wafer 400 has a front surface 100a.

FIG. 5B shows fabrication of a plurality of a first type of semiconductor based electronic device in a first semiconductor material, illustrated as light emitting diodes 106 (only one called out), with electrodes and optionally mesas. Where a first set of electronic components will be LEDs, the first semiconductor material may, for example, take the form of an epitaxial LED layer carried by the growth substrate 102. The LEDs 106 comprise a light generation or recombination region 106a (FIG. 5C) of the epitaxial LED layer 104 (FIG. 5C), and electrodes 106b (FIG. 5C). The electrodes 106b may be fabricated by depositing electrically conductive material, and patterning the electrically conductive material. Notably, the LEDs 106 are fabricated from a front surface side 108a.

FIG. 5C shows fabrication of thin film transistors (TFTs) 114 (only one called out) from the front surface side 108a. The TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114. As noted, the first semiconductor material is not limited to semiconductors suitable for formation of LEDs, and first set of electronic devices are not limited to LEDs. In other implementations, the first semiconductor material may be particularly suitable for fabrication of semiconductor based lasers, photo-detection, or high speed switching, and the first set of electronic devices may be semiconductor lasers, photodetectors, or high speed switches (e.g., high speed transistors), respectively.

FIG. 5D shows a partial releasing of the resulting structure (e.g., chiplets 110) from the growth substrate 102. The chiplets may be partially undercut, for instance via etching, and optionally masking prior to the etching. A tether 526 is left for each chiplet 110, leaving the chiplets 110 partially attached to the growth substrate 102.

FIG. 5E shows the chiplets 110 being completely released from the growth substrate by dissolving (e.g., etching) or otherwise severing (e.g., laser) the tethers 526

FIG. 5F shows the completely released chiplets 110 transferred to a target or final substrate 116 and mounted or attached thereto.

FIG. 5H shows the formation of interconnects 120 on the target or final substrate 116. Formation of interconnects 120 may comprise various depositing and patterning fabrication operations on the target or final substrate 116 to provide interconnects 120 to the drive circuitry. Such may include various silicon fabrication operations including depositing of electrically conductive materials, depositing of dielectric material, and patterning (e.g., masking, etching, polishing).

While not illustrated, one or more color conversion materials may be added. For example, one or more layers of color conversion material may be deposited, and optionally patterned on the target or final substrate 116. The depositing or patterning may cause portions of the color conversion material to be in registration with respective ones of the LEDs 106. While also not illustrated, the fabrication process can include the formation of one or more light extraction features, which may include registration of light extraction features with respective ones of the LEDs 106.

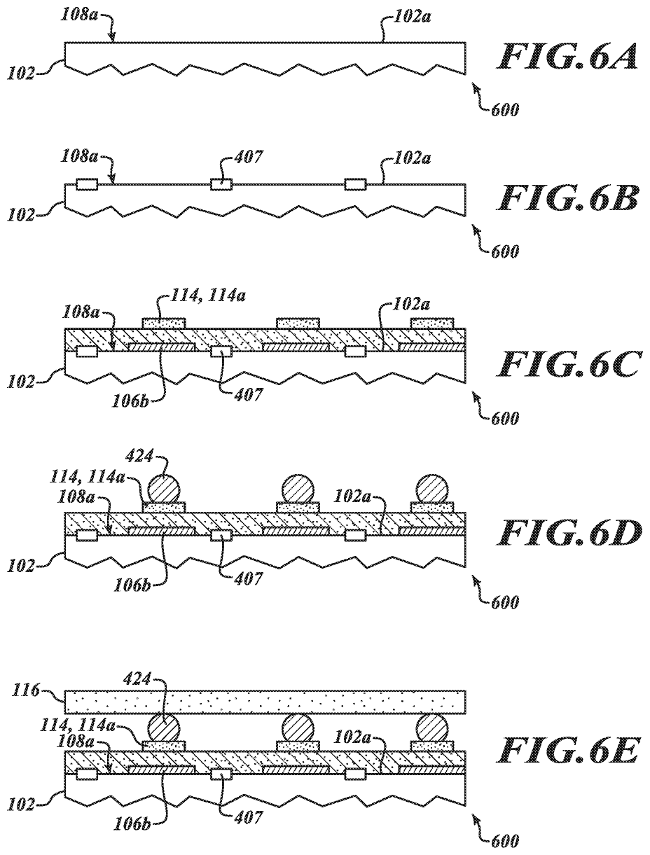

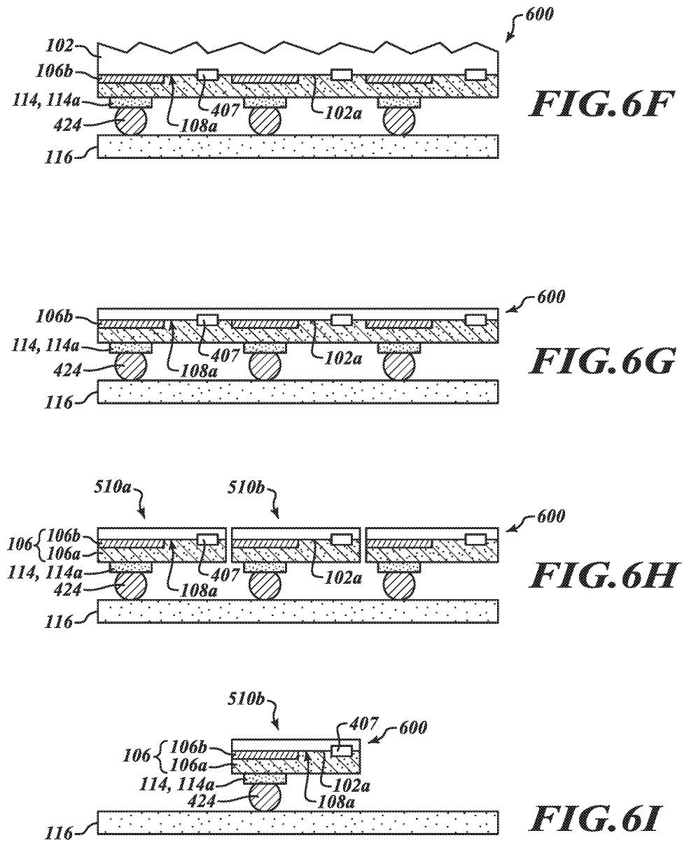

FIGS. 6A-6I show a sequence of operations to fabricate an electronic device according to at least one illustrated implementation, in which transistor circuitry is formed from a front surface side over LEDs before direct transfer, without a temporary carrier or intermediate substrate, to a final substrate in an inverted orientation via release of tethered chiplets. Many of the structures and operations are similar, or even identical, to those illustrated and described with reference to FIGS. 4A-4H and 5A-5G. These similar or identical structures and operations are identified below using the same reference numbers as used in FIGS. 4A-4H and 5A-5G.

In particular, FIG. 6A shows a light emitting diode (LED) wafer 400 comprising a growth substrate 102. The LED wafer 400 has a front surface 100a.

FIG. 6B shows fabrication of a plurality of a first type of semiconductor based electronic device in a first semiconductor material, illustrated as light emitting diodes 106 (only one called out), with electrodes 106b and optionally mesas (not shown). Where a first set of electronic components will be LEDs, the first semiconductor material may; for example, take the form of an epitaxial LED layer carried by the growth substrate 102. The LEDs 106 comprise a light generation or recombination region 106a (FIG. 60) of the epitaxial LED layer 104 (FIG. 6C), and electrodes 106b (FIG. 6C). The electrodes 106b may be fabricated by depositing electrically conductive material, and patterning the electrically conductive material. Notably, the LEDs 106 are fabricated from a front surface side 108a.

FIG. 6C shows fabrication of thin film transistors (TFTs) 114 (only one called out) from the front surface side 108a. The TFTs 114 can be formed over, or on, the LEDs 106. Such fabrication will typically include various semiconductor fabrication operations including the depositing of a second semiconductor material 114a, depositing of dielectric, and etching. Advantageously, the second semiconductor 114a material may have different physical and/or operational characteristics from the first semiconductor material 104. Thus, a semiconductor material 104 having physical or operational characteristics particularly suited to fabrication of LEDs or generation of specific wavelengths of light may be employed in fabrication of the LEDs 106, while a semiconductor material 114a having physical or operational characteristics particularly suited to fabrication of TFTs or TFT switching operation may be employed in fabrication of the TFTs 114. As noted, the first semiconductor material is not limited to semiconductors suitable for formation of LEDs, and first set of electronic devices are not limited to LEDs. In other implementations, the first semiconductor material may be particularly suitable for fabrication of semiconductor based lasers, photo-detection, or high speed switching, and the first set of electronic devices may be semiconductor lasers, photodetectors, photovoltaic cells, or high speed switches (e.g., high speed transistors), respectively.

FIG. 6D shows fabrication of contacts and connections, for example by patterning (e.g., masking and etching) and the addition of solder bumps 424 from the front surface side 108a. The LEDs 106, TFTs 114, and solder bumps 424 are structured into chiplets 410a, 410b (only two called out, collectively 410).

FIG. 6E shows partial released chiplets 110 tethered to the growth substrate 102 being attached to a target or final substrate 116. As previously described, the chiplets may be partially undercut, for instance via etching, and optionally masking prior to the etching. A tether 526 is left for each chiplet 110, leaving the chiplets 110 partially attached to the growth substrate 102.

FIG. 6F shows the completion of interconnects 120 on the target or final substrate 116. Completion of interconnects 120 may comprise various depositing and patterning fabrication operations on the target or final substrate 116 to provide interconnects 120 to the drive circuitry. Such may include various silicon fabrication operations including depositing of electrically conductive materials, depositing of dielectric material, and patterning (e.g., masking, etching, polishing).

FIG. 6G shows the chiplets 110 being completely released from the growth substrate by dissolving (e.g., etching) or otherwise severing (e.g., laser) the tethers 526

FIG. 6H shows the completely released chiplets 110 transferred to a target or final substrate 116 and mounted or attached thereto.

FIG. 6I shows a portion of the final substrate 116 after dividing, along with a respective one of the chiplets 110 mounted or attached thereto.

While not illustrated, one or more color conversion materials may be added. For example, one or more layers of color conversion material may be deposited, and optionally patterned on the target or final substrate 116. The depositing or patterning may cause portions of the color conversion material to be in registration with respective ones of the LEDs 106. While also not illustrated, the fabrication process can include the formation of one or more light extraction features, which may include registration of light extraction features with respective ones of the LEDs 106.

In any of the implementations, the physical and/or operational characteristics of a first semiconductor material may be suitable, or particularly suitable or even optimized to fabricate a particular type of semiconductor based electronic device. For example, such semiconductor based electronic devices include, but are not limited to, optoelectronic devices (e.g., semiconductor-based lasers, LEDs, photodetectors, photovoltaic or solar cells), high electron mobility transistors (e.g., HEMTs), piezoelectric devices (e.g., GaN surface acoustic wave (SAW) devices), or integrated circuits for logic and power handling.

The second semiconductor material may in some instances be the same type of semiconductor material as the first semiconductor material. However, in any of the implementations, the physical and/or operational characteristics of a second semiconductor material may be suitable, or particularly suitable or even optimized to fabricate a particular type of semiconductor based electronic device. For example, such semiconductor based electronic devices include, but are not limited to, thin film transistors, and the second semiconductor material can be any of a variety of materials suitable for fabricating TFTs, including silicon (e.g., amorphous Si, low temperature polysilicon, high temperature polysilicon, nanocrystalline silicon), germanium, metal oxides (e.g., ZnO, ZTO, IGZO, etc.), sulfides, chalcogenides, or other materials suitable for fabrication of TFTs. The second semiconductor material may in some instances be a recrystallized silicon. The semiconductor-based devices fabricated from the second semiconductor can have any of wide range of possible functionalities available using thin film devices including, but not limited to, transistors, light emitting devices, photovoltaic devices, and photodetectors.

Other combinations of device inversion, individual release, transfer to temporary structures en masse, sorting, and quality control can also be considered as options for the various fabrication processes. The deposition of color conversion layers, patterning to improve extraction or étendue, and the deposition of materials to enhance the extraction efficiency can be conducted at various operations in the various fabrication processes. The introduction of layers to facilitate the release of individual or mass layers can also be incorporated at a number of operation in the various fabrication processes. In any of the described various fabrication processes, one or more acts or operations may be omitted, and/or other acts or operations added. In at least some of the implementations, one or more acts or operations may be performed in a different order than presented.

Complete, unpatterned layer transfer can occur through a number of techniques, including, but not limited to, eutectic bonding, wafer bonding, use of temporary or permanent adhesives, use of solder or bump bonding, laser liftoff, plasma fusion, Smart Cut-style wafer release, etc.

Individual chiplet transfer can occur through a variety of techniques including, but not limited to, use of an electrostatic chuck, use of a MEMS grip head, use of elastomeric stamps, or the use of selective laser transfer processes.

Electrical connection or electrical coupling can be executed in a number of ways, including the use of solder bumps, deposited metal, indium bonding, the use of anisotropic conducting films (ACF), direct metal eutectic bonding, and fusion bonding.

U.S. provisional patent application Ser. No. 62/676,172, filed May 24, 2018; U.S. provisional patent application Ser. No. 62/787,505, filed Jan. 2, 2019; U.S. provisional patent application Ser. No. 62/783,714, filed Dec. 21, 2018; are hereby incorporated by reference, in their entireties.

The various embodiments described above can be combined to provide further embodiments. These and other changes can be made to the embodiments in light of the above-detailed description. All of the commonly assigned US patent application publications, US patent applications, foreign patents, and foreign patent applications referred to in this specification and/or listed in the Application Data Sheet, including but not limited to U.S. Provisional Patent Application No. 62/789,397, filed Jan. 7, 2019, entitled “PROCESSES, ARTICLES AND APPARATUS THAT INCORPORATE SEMICONDUCTOR SWITCHES AND DRIVE CIRCUITRY ON COMPOUND SEMICONDUCTOR CHIPLETS” are incorporated herein by reference in their entirety. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of forming circuitry, comprising:
forming a first set of circuit components in at least a first semiconductor layer of a first substrate;
forming a second set of circuit components in at least a second semiconductor layer subsequent to forming the first set of circuit components, the second semiconductor layer different from the first semiconductor layer;
forming a plurality of chiplets, the chiplets each including one or more of the circuit components from at least the first set of circuit components;
securing the chiplets to a second substrate;
communicatively coupling the second set of circuit components to one or more electrically conductive paths on the second substrate.

2. The method of claim 1, further comprising:
removing the first set of components from the first substrate to expose a back side of the first set of components.

3. The method of claim 2 wherein removing the first set of components from the first substrate to expose a back side of the first set of components includes performing at least one of a laser lift-off operation, a back-grind operation or an etching operation.

4. The method of claim 2 wherein forming the second set of circuit components includes forming the second set of circuit components on the back side of the circuit components of the first set of circuit components.

5. The method of claim 1 wherein transferring the chiplets to the second substrate includes physically coupling the chiplets to the second substrate, and subsequently fully releasing the chiplets from the first substrate.

6. The method of claim 1 wherein transferring the chiplets to the second substrate includes fully releasing the chiplets from the first substrate, and subsequently physically coupling the chiplets to the second substrate.

7. The method of claim 1 wherein transferring the chiplets to the second substrate via pick and place machinery.

8. The method of claim 1 wherein transferring the chiplets to the second substrate includes performing a selective laser operation.

9. The method of claim 1 wherein transferring the chiplets to the second substrate includes first physically coupling the chiplets to an intermediate substrate, and subsequently transferring the chiplets from the intermediate substrate to the second substrate.

10. The method of claim 9 wherein transferring the chiplets to the second substrate further includes inverting the intermediate substrate after physically coupling the chiplets to the intermediate substrate and before transferring the chiplets from the intermediate substrate to the second substrate.

11. The method of claim 1, further comprising:
partially releasing the chiplets while leaving a tether to the first substrate.

12. The method of claim 11, further comprising:
subsequently removing the tether of one or more of the chiplets to fully release the chiplet.

13. The method of claim 1, further comprising:
reflowing a set of solder bumps to form one or more electrically connections between the circuit components of the first set of circuit components and the circuit components of the second set of circuit components.

14. The method of claim 1 wherein forming a first set of circuit components comprises forming a first set of light emitting diodes (LEDs).

15. The method of claim 14 wherein forming a second set of circuit components comprises forming a second set of transistors, communicatively coupled to respective ones of the LEDs of the first set of LEDs.

16. The method of claim 1 wherein forming a first set of circuit components in at least a first semiconductor layer comprises forming the first set of circuit components in the first semiconductor layer having a first set of operational characteristics that are relatively more suitable to the first set of circuit components than the second set of circuit components and forming a second set of circuit components in at least a second semiconductor layer comprises forming the second set of circuit components in the second semiconductor layer having a second set of operational characteristics that are relatively more suitable to the second set of circuit components than the first set of circuit components.

17. The method of claim 1 wherein forming a first set of circuit components in at least a first semiconductor layer comprises forming a first set of semi-conductor photo-detectors.

18. The method of claim 1 wherein forming a first set of circuit components in at least a first semiconductor layer comprises forming a first set of one of the group consisting of: light emitting diodes, semi-conductor based lasers; semi-conductor photo-detectors; and high electron mobility transistors.

19. The method of claim 1 wherein forming a first set of circuit components in at least a first semiconductor layer comprises forming a set of opto-electronics and forming a second set of circuit components in at least a second semiconductor layer comprises forming a set of transistors.

20. The method of claim 1 wherein forming a second set of circuit components in at least a second semiconductor layer comprises forming a set of transistors in a recrystallized layer of silicon.

21.-92. (canceled)
